(19) United States
(12) Patent Application Publication
(10) Pub. No.: US 2005/0062152 A1
(43) Pub. Date: Mar. 24, 2005

(54) Window ball grid array semiconductor package with substrate having opening and mehtod for fabricating the same

(76) Inventor: Chung-Che Tsai, Hsiu-chu (TW)

Correspondence Address: ANDERSON KILL & OLICK, P.C., 1251 Avenue of Americas, New York, NY, 10020, US

(21) Appl. No.: 10/671,176

(22) Filed: Sep. 24, 2003

(51) Int. Cl. H01L 23/48

(52) U.S. Cl. 257/737; 438/613

(57) ABSTRACT

A window ball grid array (WBGA) semiconductor package and a fabrication method thereof are provided. This WBGA package includes: a substrate having a through opening; a chip mounted on an upper surface and over the opening of the substrate via an adhesive, and electrically connected to a lower surface of the substrate via bonding wires through the opening, with gaps, not applied with the adhesive, formed between the chip and the substrate; a first encapsulation body made of a resin material for encapsulating the chip and the bonding wires, allowing the resin material to pass through the gaps to fill the opening of the substrate and the gaps; a second encapsulation body for covering the part of the first encapsulation body on the lower surface of the substrate; and a plurality of solder balls bonded to area free of the second encapsulation body on the lower surface of the substrate.

### FIELD OF THE INVENTION

The present invention relates to semiconductor packages, and more particularly, to a window ball grid array (WBGA) semiconductor package having a chip mounted over an opening formed through a substrate and electrically connected to the substrate via bonding wires going through the opening.

### BACKGROUND OF THE INVENTION

Semiconductor packages are electronic devices incorporated with active components such as semiconductor chips, whose structure is primarily composed of at least one semiconductor chip mounted on a side of substrate and electrically connected to the substrate by means of conductive elements such as bonding wires; an encapsulation body made of a resin material (such as epoxy resin, etc.) is formed on the substrate to encapsulate the chip and bonding wires which are protected against external moisture and contaminant. The semiconductor package may further comprise an array of solder balls bonded to a side of the substrate opposite to the side mounted with the chip and bonding wires. Such a semiconductor package having solder balls is named as BGA (ball grid array) package, and the solder balls serve as input/output (I/O) connections to allow the incorporated chip to be in electrical connection with an external device such as printed circuit board (PCB). The height of the semiconductor package takes into account of the thickness of the encapsulation body that encapsulates the chip and bonding wires, the thickness of the substrate, and the height of the solder balls, making the size of the semiconductor package difficult to be further reduced.

In order to make the semiconductor package more compact in size, a window-type package is provided which is named as to an opening formed through the substrate. As shown in FIG. 4F of a conventional window ball grid array (WBGA) semiconductor package, a semiconductor chip 11 is mounted on an upper surface 100 of the substrate 10 and over the opening 102 by means of an adhesive 12. The chip 11 is electrically connected to a lower surface 101 of the substrate 10 by a plurality of bonding wires 13 going through the opening 102. The chip 11 and the bonding wires 13 are respectively encapsulated by an upper encapsulation body 14 and a lower encapsulation body 15 which are separately fabricated. A plurality of solder balls 16 are implanted on the lower surface 101 of the substrate 10 at area free of the lower encapsulation body 15.

The above WBGA semiconductor package is fabricated by the procedural steps shown in FIGS. 4A-4F.

First referring to FIG. 4A (a top view and a cross-sectional view taken along line 4A-4A in the top view), a substrate plate 1 integrally formed by a plurality of the substrate 10 is prepared, wherein each substrate 10 has an opening 102 penetrating therethrough, and the opening 102 is preferably shaped as a rectangle having two longer sides and two shorter sides. Next, a chip-bonding process and then a wire-bonding process are performed. During chip-bonding, at least one chip 11 is mounted on an upper surface 100 of each of the substrates 10 and over the opening 102 of the corresponding substrate 10 by means of the adhesive 12 that is applied along the two longer sides of the opening 102, leaving gaps G along the two shorter sides of the opening 102 being formed between the chip 11 and the substrate 10 and not filled by the adhesive 12. Then, during wire-bonding, a plurality of bonding wires 13 are formed through the opening 102 of each of the substrates 10 to electrically connect the chip 11 to a lower surface 101 of the corresponding substrate 10. Subsequently referring to FIG. 4B (a bottom view and a cross-sectional view taken along line 4B-4B in the bottom view), an encapsulation mold having an upper mold 17 and a lower mold 18 is prepared, wherein the upper mold 17 is formed with an upwardly recessed cavity 170, and the lower mold 18 is formed with a plurality of downwardly recessed cavities 180 each corresponding to a row of the openings 102 of the substrates 10. The upwardly recessed cavity 170 is sized to receive all the chips 11 mounted on the substrates 10 therein. Each of the downwardly recessed cavities 180 is sized to cover all the openings 102 of the corresponding row of the substrates 10 and accommodate wire loops of the bonding wires 13 protruding from the lower surfaces 101 of the corresponding row of the substrates 10. The encapsulation mold is coupled to the substrate plate 1 with the upper mold 17 mounted on the upper surfaces 100 of the substrates 10 and the lower mold 18 attached to the lower surfaces 101 of the substrates 10.

Referring to FIG. 4C (two cross-sectional views vertically taken with respect to each other), a first molding process is performed and a conventional resin material (such as epoxy resin) is injected into the downwardly recessed cavities 180 of the lower mold 18 to form a plurality of lower encapsulation bodies 15 each filling the corresponding row of the openings 102 and encapsulating the corresponding bonding wires 13, while the gaps G between the chips 11 and the substrates 10 usually fail to be completely filled by the resin material.

Then, referring to FIG. 4D, a second molding process is performed and the resin material is injected into the upwardly recessed cavity 170 of the upper mold 17 to form an upper encapsulation body 14 that encapsulates all the chips 11 mounted on the substrates 10.

After the first and second molding processes are complete, the upper and lower molds 17, 18 are removed from the substrate plate 1, making area on the lower surfaces 101 of the substrates 10, not covered by the lower encapsulation bodies 15, exposed outside.

Referring to FIG. 4E, a plurality of solder balls 16 are bonded to the exposed area on the lower surface 101 of each of the substrates 10. Finally, the substrate plate 1, after undergoing the above chip-bonding, wire-bonding, molding, and ball-bonding processes, is subject to a singulation process which cuts the upper encapsulation body 14, the substrate plate 1, and the lower encapsulation bodies 15 to separate apart the integrally formed substrates 10 and thus form a plurality of individual semiconductor packages each incorporated with a singulated substrate 10 and a chip 11 therein and have a plurality of the solder balls 16 thereon as shown in FIG. 4F.

However, the above fabrication method for the semiconductor package would lead to significant drawbacks. First, during cutting the lower encapsulation body formed over the openings of each row of the substrates, an intersecting portion between the lower encapsulation body and the boundary of the substrates would be subject to severe stresses which may cause delamination at the intersecting portion due to different materials used for making the encapsulation body and the substrate. Second, the downwardly recessed cavity formed in the lower mold is sized in accordance with the size of the substrate opening to allow the lower encapsulation body to completely cover the opening but not occupy area on the lower surface of the substrate predetermined for bonding the solder balls. In other words, when using substrates having openings of different sizes, new lower molds having correspondingly-dimensioned downwardly recessed cavities are required which would however greatly increase the fabrication costs. Moreover, the encapsulation process is performed in two stages: the first stage is to form the lower encapsulation body for filling the opening and encapsulating the bonding wires, and the second stage is to form the upper encapsulation body for encapsulating the chip. Such a two-stage encapsulation process not only complicates the fabrication performance but also leads to a resin-flash problem. During the first encapsulation process for forming the lower encapsulation body, area on the lower surface of the substrate around the opening and underneath the chip usually lacks firm support from the upper mold and is not strongly clamped by the encapsulation mold, such that the resin material injected into the downwardly recessed cavity of the lower mold may easily leak or flash through the edge of the opening to the area, not strongly clamped by the encapsulation mold, on the lower surface of the substrate. The resin flash may even contaminate predetermined ball-bonding area on the lower surface of the substrate, making the solder balls not able to be well bonded or electrically connected to the substrate, and thereby degrading the reliability of the semiconductor package. Besides, as the gaps between the chip and the substrate and along shorter sides of the substrate opening are usually not completely filled by the resin material, voids may reside in the gaps and undesirably cause popcorn effect, such that the package structure would be damaged. In addition, injection of the resin material into the downwardly recessed cavity of the lower mold may generate great resin flow impact which would cause sweep of the bonding wires and undesirable contact between adjacent wires, leading to short circuits and also degrading the reliability of the semiconductor package.

Therefore, the problem to be solved herein is to provide a WBGA semiconductor package which can resolve the above drawbacks to thereby prevent delamination, avoid resin flash, eliminate wire sweep, and reduce fabrication costs and process complexity.

### SUMMARY OF THE INVENTION

An objective of the present invention is to provide a window ball grid array (WBGA) semiconductor package and a method for fabricating the same, by which a molding process is performed using a flat lower mold and a cheap spacer that is made to comply with substrates having variously-sized openings, to thereby effectively reduce the fabrication costs and simplify the fabrication processes.

Another objective of the invention is to provide a WBGA semiconductor package and a method for fabricating the same, by which during molding, gaps between a chip and the substrate serve as passages for resin flow which fills an opening of the substrate without generating great impact to bonding wires, thereby preventing wire sweep and resin flash.

A further objective of the invention is to provide a WBGA semiconductor package and a method for fabricating the same, by which the opening of each substrate is filled and covered by a single encapsulation body, thereby avoiding delamination as cutting or singulation of such an encapsulation body is not required.

A further objective of the invention is to provide a WBGA semiconductor package and a method for fabricating the same, by which an integral encapsulation body encapsulates the chip and bonding wires are encapsulated and fills the opening of the substrate, thereby enhancing mechanical strength of the semiconductor package.

A further objective of the invention is to provide a WBGA semiconductor package and a method for fabricating the same, by which another encapsulation body is formed to perfect outer appearance of the integral encapsulation body that directly the chip and bonding wires are encapsulated and fills the opening of the substrate and further assure complete encapsulation of the bonding wires.

In accordance with the foregoing and other objectives, the present invention proposes a WBGA semiconductor package, comprising: a substrate having an upper surface and an opposite lower surface and having an opening formed through the same; at least one chip mounted on the upper surface and over the opening of the substrate via an adhesive, and electrically connected to the lower surface of the substrate via a plurality of bonding wires going through the opening, with gaps, not applied with the adhesive, being formed between the chip and the substrate; a first molded encapsulation body made of a resin material and formed on the upper and lower surfaces of the substrate for encapsulating the chip and the bonding wires, wherein the gaps between the chip and the substrate allow the resin material to pass therethrough to fill the opening of the substrate and the gaps; a second non-molded encapsulation body for covering the part of the first encapsulation body on the lower surface of the substrate; and a plurality of solder balls bonded to area free of the second encapsulation body on the lower surface of the substrate and exposed outside.

The above semiconductor package is fabricated in a batch manner by the following steps comprising: preparing a substrate plate integrally formed of a plurality of substrates each of which has an upper surface and an opposite lower surface and has an opening formed through the same; mounting at least one chip on the upper surface and over the opening of each of the substrates via an adhesive, with gaps, not applied with the adhesive, being formed between the chips and the corresponding substrates; forming a plurality of bonding wires through the opening of each of the substrates for electrically connecting the chip to the lower surface of the corresponding substrate; attaching a spacer having a plurality of through holes to the lower surfaces of the substrates, wherein each of the through holes corresponds to and is larger than the opening of each of the substrates, and the spacer has a thickness larger than a height of wire loops of the bonding wires protruding from the lower surfaces of the substrates so as to allow the bonding wires bonded to each of the chips to be received in the corresponding through hole of the spacer and the opening of the corresponding substrate; performing a molding process to form a first encapsulation body on upper and lower surfaces of the substrates by a resin material that is injected over the upper surfaces of the substrates to encapsulate the chips and flows through the gaps between the chips and the corresponding substrates to fill the openings of the substrates, the through holes of the spacer, and the gaps and to encapsulate the bonding wires; removing the spacer from the substrates, such that the first encapsulation body formed on the substrates is exposed; forming a second non-molded encapsulation body to cover the part of the first encapsulation body on the lower surface of each of the substrates; bonding a plurality of solder balls to area free of the second encapsulation body on the lower surface of each of the substrates; and cutting the part of the first encapsulation body on the upper surfaces of the substrates and the substrate plate to separate apart the integrally formed substrates and form a plurality of individual semiconductor packages each having a singulated substrate.

The above semiconductor package yields significant benefits. Since the gaps that are not applied with the adhesive and between the chip and the substrate and along shorter sides of the opening of the substrate serve as passages for flow of the resin material forming the first encapsulation body. During molding, once the resin material is injected into the cavity of the upper mold where the chip is received, it fills the mold cavity and flows through the gaps or passages to fill the opening and encapsulate the bonding wires and also fill the gaps, such that the prior-art problem of void or popcorn effect is avoided. Moreover, the resin flow through the gaps or passages would not generate great impact or pressure on the bonding wires, and thereby prevents wire sweep or short circuits from occurrence. Further due to the reduced resin-flow impact or pressure, the resin material would unlikely flash through the opening edge to unintended area on the lower surface of the substrate or contaminate predetermined ball-bonding area, thereby assuring the reliability of the fabricated package. Moreover, a spacer having a through hole sized in accordance with the opening of the substrate is clamped between the lower surface of the substrate and the lower mold which is flat in surface. The through hole is also filled with the resin material that encapsulates the bonding wires. The spacer is cheaply fabricated, such that when using substrates having openings of different sizes, spacers formed with correspondingly-sized through holes can be used without significantly increasing the fabrication costs. As such, the flat lower mold is universal for use with various substrates in accompany with appropriate spacers. Besides, the first encapsulation body integrally encapsulates the chip and the bonding wires and fills the opening of the substrate, which thereby enhances the mechanical strength of the semiconductor package. Further as the first encapsulation body independently fills and covers the opening of each substrate, no cutting or singulation of the first encapsulation body formed on the lower surface of each substrate is required, such that the prior-art problem of delamination between the encapsulation body and the substrate is eliminated. In addition, a second non-molded encapsulation body is formed over the first encapsulation body on the lower surface of each substrate to perfect the outer appearance of the semiconductor package and also assure the bonding wires being completely encapsulated, and the second encapsulation body is fabricated by the conventional dispensing or printing technique without significantly increasing the fabrication complexity and costs.

### BRIEF DESCRIPTION OF THE DRAWINGS

The present invention can be more fully understood by reading the following detailed description of the preferred embodiments, with reference made to the accompanying drawings, wherein:

FIG. 1 is a cross-sectional view of a semiconductor package according to a first preferred embodiment of the invention;

FIGS. 2A-2G are schematic diagrams showing procedural steps for fabricating the semiconductor package shown in FIG. 1;

FIG. 3 is a cross-sectional view of a semiconductor package according to a second preferred embodiment of the invention; and

FIGS. 4A-4F (PRIOR ART) are schematic diagrams showing procedural steps for fabricating a conventional semiconductor package.

### DETAILED DESCRIPTION OF THE PREFERRED EMBODIMENTS

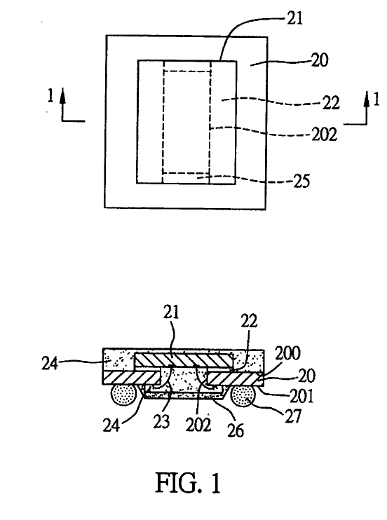

The preferred embodiments of a window ball grid array (WBGA) semiconductor package and a method for fabricating the same proposed in the present invention are described with reference to FIGS. 1, 2A-2G and 3.

First Preferred Embodiment

As shown in FIG. 1 (a top view and a cross-sectional view taken along line 1-1 in the top view), a WBGA semiconductor package according to a first preferred embodiment of the invention uses a substrate 20 as a chip carrier, comprising: the substrate 20 having an upper surface 200 and an opposite lower surface 201 and having an opening 202 penetrating through the same; at least one chip 21 mounted on the upper surface 200 and over the opening 202 of the substrate 20 via an adhesive 22, and electrically connected to the lower surface 201 of the substrate 20 via a plurality of bonding wires 23 going through the opening 202, with gaps 25, not applied with the adhesive 22, being formed between the chip 21 and the substrate 20; a first molded encapsulation body 24 formed on the upper and lower surfaces 200, 201 of the substrate 20 for encapsulating the chip 21 and the bonding wires 23 and filling the opening 202 of the substrate 20 and the gaps 25 between the chip 21 and the substrate 20; a second non-molded encapsulation body 26 for covering the part of the first encapsulation body 24 on the lower surface 201 of the substrate 20; and a plurality of solder balls 27 bonded to area free of the second encapsulation body 26 on the lower surface 201 of the substrate 20 and exposed outside.

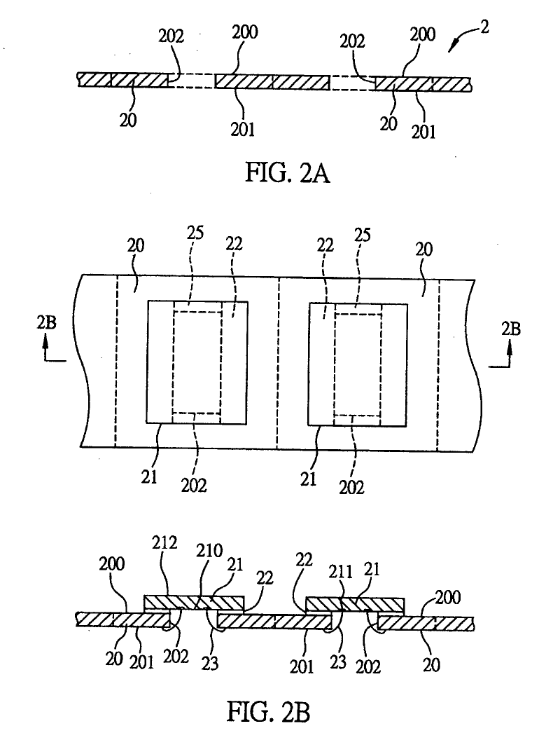

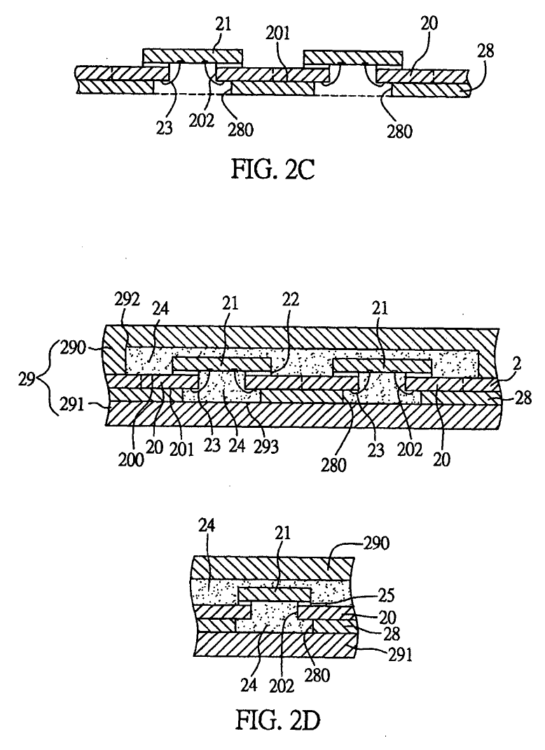

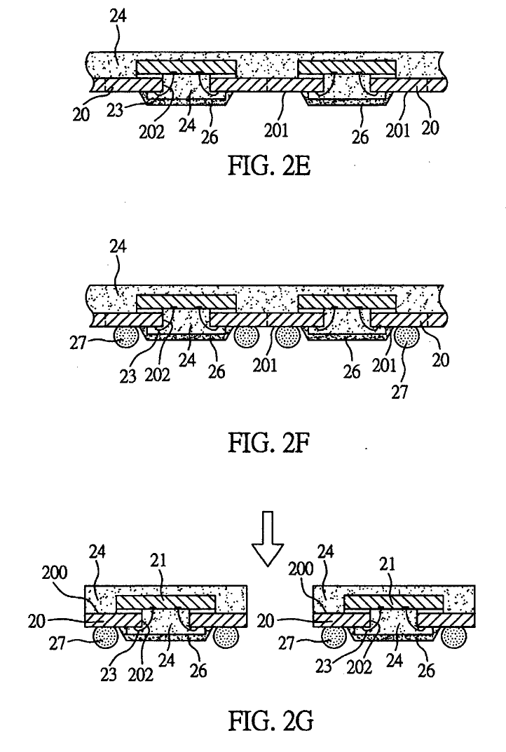

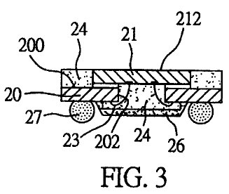

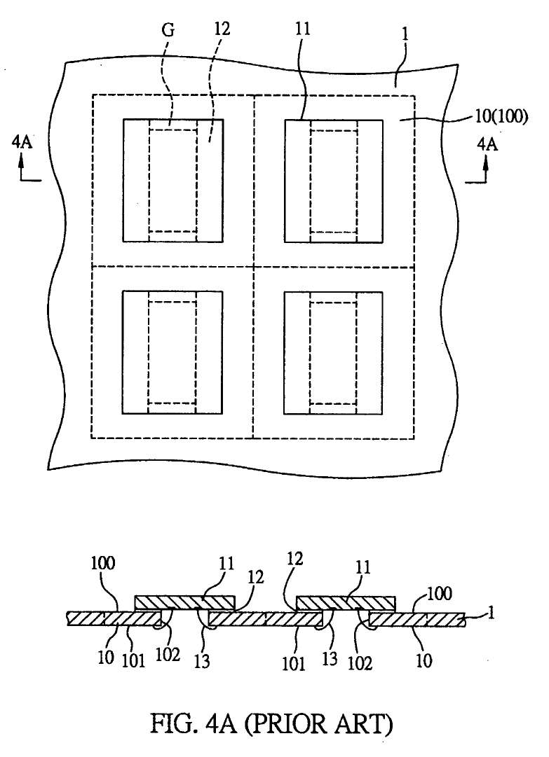

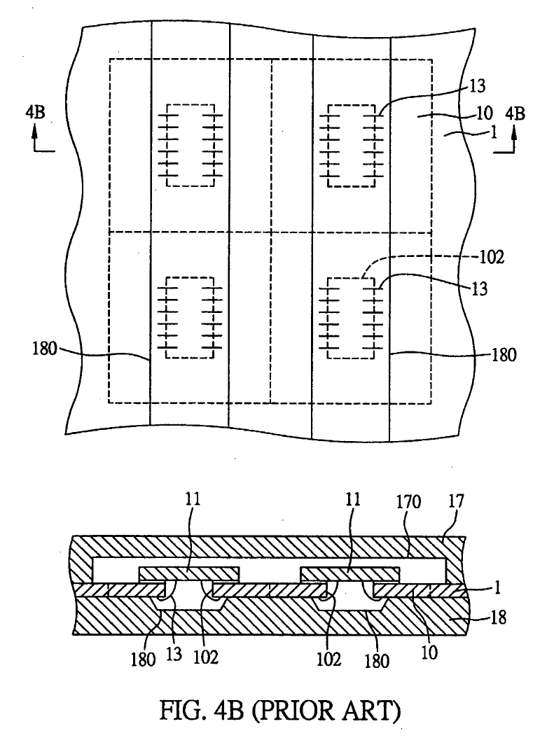

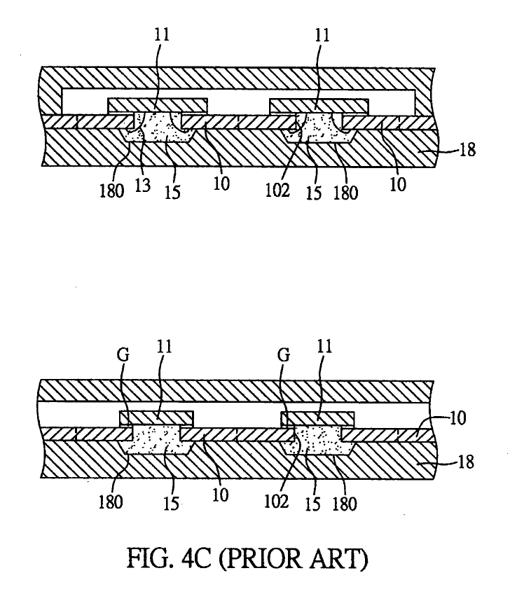

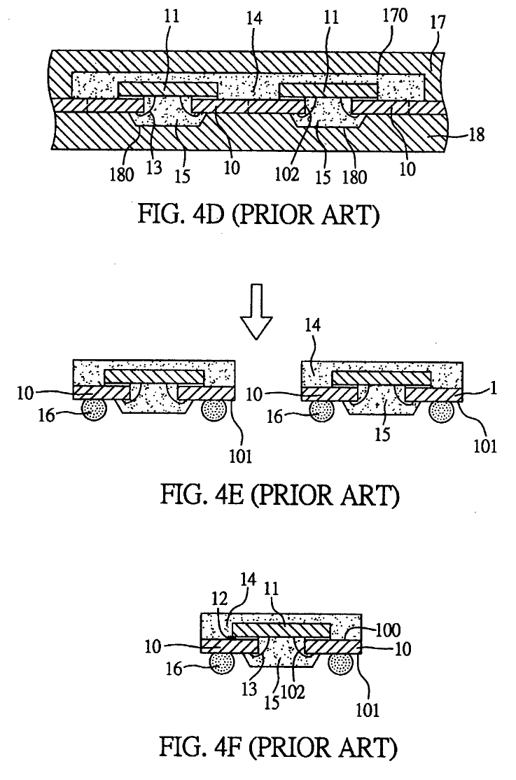

The above WBGA semiconductor package can be fabricated by a series of procedural steps illustrated in FIGS. 2A-2G.

Referring to FIG. 2A, the first step is to prepare substrate plate 2 integrally formed of a plurality of substrates 20, which can be made of a conventional resin material such as epoxy resin, polyimide resin, BT (bismaleimide triazine) resin, FR4 resin, etc. Each of the substrates 20 has an upper surface 200 and an opposite lower surface 201 and has an opening 202 penetrating through the same, wherein the opening 202 is preferably of a rectangular shape having two opposite longer sides and two opposite shorter sides. Fabrication of the substrate plate 2 employs conventional technology and is not to be further detailed herein.

Referring to FIG. 2B (a top view and a cross-sectional view taken along line 2B-2B in the top view), the next step is to mount at least one chip 21 on the upper surface 200 and over the opening 202 of each of the substrates 20 via an adhesive 22. The chip 21 has an active surface 210 where a plurality of electronic circuits (not shown) and bond pads 211 are formed, and an opposite inactive surface 212. The chip 21 is sized larger in surface area than the opening 202 of the corresponding substrate 20 to entirely cover the opening 202. The chip 21 is mounted in a face-down manner on the corresponding substrate 20 that the active surface 210 faces the opening 202 and is attached to the upper surface 200 of the corresponding substrate 20 by means of the adhesive 22 which is applied between the chip 21 and the substrate 20 and along the two longer sides of the opening 202, leaving gaps 25 not applied with the adhesive 22 to be formed between the chip 21 and the substrate 20 and along the two shorter sides of the opening 202. The adhesive 22 is applied in a predetermined thickness, making the gaps 25 between the chip 21 and the substrate 20 have a height equal to the thickness of the adhesive 22, which thickness or height is predetermined to allow particles of a resin material subsequently used for forming an encapsulation body (not shown) to be able to smoothly pass through the gaps 25.

Then, a wire-bonding process is carried out to form a plurality of bonding wires 23 through the opening 202 of each of the substrates 20, wherein the bonding wires 23 are bonded to the bond pads 211 on the chip 21 and to the lower surface 201 of the corresponding substrate 20 so as to electrically connect the chip 21 to the substrate 20. The bonding wires 23 can be made of gold. The wire-bonding process pertains to conventional technology and is not to be further described herein.

Referring to FIG. 2C, a spacer 28, preferably made of a rigid material, is prepared having a plurality of through holes 280 and attached to the lower surfaces 201 of the substrates 20. Each of the through holes 280 corresponds to and is larger than the opening 202 of each of the substrates 20. The spacer 28 is sized in thickness larger than a height of wire loops of the bonding wires 23 protruding from the lower surfaces 201 of the substrates 20, so as to allow the wire loops of the bonding wires 23 bonded to each of the chips 21 to be received in the corresponding through hole 280 of the spacer 28.

Referring to FIG. 2D (two cross-sectional views vertically taken with respect to each other), thereafter, a molding process is performed and uses a conventional resin material (e.g. epoxy resin) to form a first encapsulation body 24 on the upper and lower surfaces 200, 201 of the substrates 20. An encapsulation mold 29 having an upper mold 290 and a lower mold 291 is employed, wherein the upper mold 290 is formed with a cavity 292 sized sufficiently to cover all chips 21 mounted on the substrates 20, and the lower mold 291 is a flat mold having a flat top surface 293 to be in contact with the spacer 28. For implementing the molding process, the chip-bonded and wire-bonded substrate plate 2 is disposed and clamped between the upper and lower molds 290, 291 of the encapsulation mold 29. The upper mold 290 abuts against the upper surfaces 200 of substrates 20, allowing the chips 21 mounted on the substrates 20 to be received in the cavity 292 of the upper mold 290. The lower mold 291 comes into contact with the spacer 28, allowing the spacer 28 to be interposed between the lower surfaces 201 of the substrates 20 and the top surface 293 of the lower mold 291, such that the bonding wires 23 reside in a combined cavity which is formed by the opening 202 of each of the substrates 20 and the corresponding through hole 280 of the spacer 28 and sealed by the lower mold 291. The resin material is injected into the cavity 292 of the upper mold 290 to fill the entire cavity 292 and encapsulate all the chips 21 mounted on the substrates 20. The resin material also flows from the cavity 292 of the upper mold 290 through the gaps 25 between the chips 21 and the substrates 20 into the openings 202 of the substrates 20 and the through holes 280 of the spacer 28. The height of the gaps 25 as defined above is sufficient to permit smooth movement of the particles of the resin material through the gaps 25, such that the resin material can encapsulate the bonding wires 23 and fill each of the combined cavities formed by the openings 202 of the substrates 20 and the through holes 280 of the spacer 28, as well as fill the gaps 25 between the chips 21 and the substrates 20. When the resin material is cured, the first encapsulation body 24 integrally molded on the upper and lower surfaces 200, 201 of the substrates 20 is fabricated, wherein the part of the first encapsulation body 24 on the upper surfaces 200 of the substrates 20 is a single body which encapsulates all the chips 21, and the part of the first encapsulation body 24 on the lower surfaces 201 of the substrates 20 comprises a plurality of separate subunits each filling the combined cavity of the corresponding opening 202 and through hole 280 and filling the gaps 25 between the corresponding chip 21 and substrate 20. Since the thickness of the spacer 28 is larger than the height of wire loops of the bonding wires 23 protruding from the lower surfaces 201 of the substrates 20, the resin material filling the through holes 280 of the spacer 28 would completely encapsulate the wire loops. Further, since the spacer 28 is made of a rigid material and the top surface 293 of the lower mold 291 is flat, the spacer 28 can be strongly clamped between the substrate plate 2 and the lower mold 291 and thereby helps prevent the resin material from flashing to the interface between the spacer 28 and the top surface 293 of the lower mold 182 and over unintended area on the lower surfaces 201 of the substrates 20.

After the first encapsulation body 24 is formed, the encapsulation mold 29 and the spacer 28 are removed from the substrates 20, such that the part of the first encapsulation body 24 on the lower surfaces 201 of the substrates 20 is exposed. However, this part of the first encapsulation body 24 comprising the plurality of subunits is formed by the resin material passing through the gaps 25 between the chips 21 and the substrates 20 and may be defective in its outer appearance. And accidentally, in case of the defective appearance of the first encapsulation body 24 not perfectly encapsulating the bonding wires 23 or undesirably exposing the bonding wires 23, this would severely affect the quality and reliability of the intended fabricated packages.

Referring to FIG. 2E, a dispensing or printing process is carried out to form a second encapsulation body 26 over each of the subunits of the part of the first encapsulation body 24 on the lower surfaces 201 of the substrates 20 to remedy the defective appearance of the first encapsulation body 24 and perfect the encapsulation of the bonding wires 23.

Referring to FIG. 2F, predetermined area on the lower surface 201 of each of the substrates 20, not covered by the first encapsulation body 24 and the second encapsulation body 26, is exposed outside and subject to a ball-implanting process by which a plurality of solder balls 27 are formed thereon. And the combined thickness of the first encapsulation body 24 and the second encapsulation body 26 protruding on the lower surface 201 of the substrate 20 is smaller than the height of the solder balls 27.

Referring to FIG. 2G, finally, a singulation process is performed to cut the first encapsulation body 24 partly formed on the upper surfaces 200 of the substrates 20 and the substrate plate 2 to separate apart the integrally formed substrates 20 and thereby form a plurality of individual semiconductor packages each having a singulated substrate 20 and a plurality of solder balls 27 as shown in FIG. 1. The solder balls 27 serve as input/output (I/O) connections to allow the chip 21 in each semiconductor package to be in electrical connection with an external device such as printed circuit board (PCB).

The above semiconductor package yields significant benefits. Since the gaps that are not applied with the adhesive and between the chip and the substrate and along shorter sides of the opening of the substrate serve as passages for flow of the resin material forming the first encapsulation body. During molding, once the resin material is injected into the cavity of the upper mold where the chip is received, it fills the mold cavity and flows through the gaps or passages to fill the opening and encapsulate the bonding wires and also fill the gaps, such that the prior-art problem of void or popcorn effect is avoided. Moreover, the resin flow through the gaps or passages would not generate great impact or pressure on the bonding wires, and thereby prevents wire sweep or short circuits from occurrence. Further due to the reduced resin-flow impact or pressure, the resin material would unlikely flash through the opening edge to unintended area on the lower surface of the substrate or contaminate predetermined ball-bonding area, thereby assuring the reliability of the fabricated package. Moreover, a spacer having a through hole sized in accordance with the opening of the substrate is clamped between the lower surface of the substrate and the lower mold which is flat in surface. The through hole is also filled with the resin material that encapsulates the bonding wires. The spacer is cheaply fabricated, such that when using substrates having openings of different sizes, spacers formed with correspondingly-sized through holes can be used without significantly increasing the fabrication costs. As such, the flat lower mold is universal for use with various substrates in accompany with appropriate spacers. Besides, the first encapsulation body integrally encapsulates the chip and the bonding wires and fills the opening of the substrate, which thereby enhances the mechanical strength of the semiconductor package. Further as the first encapsulation body independently fills and covers the opening of each substrate, no cutting or singulation of the first encapsulation body formed on the lower surface of each substrate is required, such that the prior-art problem of delamination between the encapsulation body and the substrate is eliminated. In addition, a second non-molded encapsulation body is formed over the first encapsulation body on the lower surface of each substrate to perfect the outer appearance of the semiconductor package and also assure the bonding wires being completely encapsulated, and the second encapsulation body is fabricated by the conventional dispensing or printing technique without significantly increasing the fabrication complexity and costs.

Second Preferred Embodiment

FIG. 3 illustrates a semiconductor package according to a second preferred embodiment of the invention. As shown in FIG. 3, this semiconductor package is structurally similar to that of the above first embodiment (FIG. 1) but differs in that the inactive surface 212 of the chip 21 is not encapsulated by the first encapsulation body 24 and exposed outside. This exposed surface 212 of the chip 21 desirably facilitates the dissipation of heat generated from operation of the chip 21, thereby improving the heat dissipating efficiency of the semiconductor package.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

1. A window ball grid array (WBGA) semiconductor package, comprising:
a substrate having an upper surface and an opposite lower surface and having an opening formed through the same;
at least one chip mounted on the upper surface and over the opening of the substrate via an adhesive, and electrically connected to the lower surface of the substrate via a plurality of bonding wires going through the opening, with gaps, not applied with the adhesive, being formed between the chip and the substrate;
a first molded encapsulation body made of a resin material and formed on the upper and lower surfaces of the substrate for encapsulating the chip and the bonding wires, wherein the gaps between the chip and the substrate allow the resin material to pass therethrough to fill the opening of the substrate and the gaps;
a second non-molded encapsulation body for covering the part of the first encapsulation body on the lower surface of the substrate; and
a plurality of solder balls bonded to area free of the second encapsulation body on the lower surface of the substrate and exposed outside.

2. The semiconductor package of claim 1, wherein the second encapsulation body is dispensed on the lower surface of the substrate.

3. The semiconductor package of claim 1, wherein the second encapsulation body is printed on the lower surface of the substrate.

4. The semiconductor package of claim 1, wherein the chip has an active surface and an opposite inactive surface, and the active surface faces the opening and is connected with the bonding wires, allowing the active surface to be entirely encapsulated by the adhesive and the first encapsulation body.

5. The semiconductor package of claim 4, wherein the inactive surface of the chip is exposed to outside of the first encapsulation body.

6. The semiconductor package of claim 1, wherein the opening is of a rectangular shape having two opposite longer sides and two opposite shorter sides.

7. The semiconductor package of claim 6, wherein the gaps between the chip and the substrate are located along the two shorter sides of the opening.

8. The semiconductor package of claim 1, wherein the gaps have a height equal to a thickness of the adhesive which is predetermined to allow particles of the resin material to pass through the gaps.

9. The semiconductor package of claim 7, wherein the gaps have a height equal to a thickness of the adhesive which is predetermined to allow particles of the resin material to pass through the gaps.

10. A method for fabricating a window ball grid array (WBGA) semiconductor package, comprising the steps of:
preparing a substrate plate integrally formed of a plurality of substrates each of which has an upper surface and an opposite lower surface and has an opening formed through the same;
mounting at least one chip on the upper surface and over the opening of each of the substrates via an adhesive, with gaps, not applied with the adhesive, being formed between the chips and the corresponding substrates;
forming a plurality of bonding wires through the opening of each of the substrates for electrically connecting the chip to the lower surface of the corresponding substrate;
attaching a spacer having a plurality of through holes to the lower surfaces of the substrates, wherein each of the through holes corresponds to and is larger than the opening of each of the substrates, and the spacer has a thickness larger than a height of wire loops of the bonding wires protruding from the lower surfaces of the substrates so as to allow the bonding wires bonded to each of the chips to be received in the corresponding through hole of the spacer and the opening of the corresponding substrate;
performing a molding process to form a first encapsulation body on upper and lower surfaces of the substrates by a resin material that is injected over the upper surfaces of the substrates to encapsulate the chips and flows through the gaps between the chips and the corresponding substrates to fill the openings of the substrates, the through holes of the spacer, and the gaps and to encapsulate the bonding wires;
removing the spacer from the substrates, such that the first encapsulation body formed on the substrates is exposed;
forming a second non-molded encapsulation body to cover the part of the first encapsulation body on the lower surface of each of the substrates;
bonding a plurality of solder balls to area free of the second encapsulation body on the lower surface of each of the substrates; and
cutting the part of the first encapsulation body on the upper surfaces of the substrates and the substrate plate to separate apart the integrally formed substrates and form a plurality of individual semiconductor packages each having a singulated substrate.

11. The method of claim 10, wherein the second encapsulation body is formed on the lower surface of the substrate by a dispensing process.

12. The method of claim 10, wherein the second encapsulation body is formed on the lower surface of the substrate by a printing process.

13. The method of claim 10, wherein the chip has an active surface and an opposite inactive surface, and the active surface faces the opening and is connected with the bonding wires, allowing the active surface to be entirely encapsulated by the adhesive and the first encapsulation body.

14. The method of claim 13, wherein the inactive surface of the chip is exposed to outside of the first encapsulation body.

15. The method of claim 11, wherein the opening is of a rectangular shape having two opposite longer sides and two opposite shorter sides.

16. The method of claim 15, wherein the gaps between the chip and the substrate are located along the two shorter sides of the opening.

17. The method of claim 10, wherein the gaps have a height equal to a thickness of the adhesive which is predetermined to allow particles of the resin material to pass through the gaps.

18. The method of claim 16, wherein the gaps have a height equal to a thickness of the adhesive which is predetermined to allow particles of the resin material to pass through the gaps.

19. The method of claim 10, wherein the spacer is made of a rigid material.
